(19) United States
(12) Patent Application Publication
(10) Pub. No.: US 2007/0259616 A1
(43) Pub. Date: Nov. 8, 2007

(54) Apparatus for conditioning racks for electrical, electronic and telecommunications instruments and the like

(75) Inventors: Mario Scattolin, Scorze (IT); Alberto Ranzato, Piove Di Sacco (IT); Carlo Girotto, Masera (IT)

Correspondence Address: MODIANO & ASSOCIATI, Via Meravigli, 16, MILAN, 20123, omitted

(73) Assignee: EMERSON NETWORK POWER S.R.L.

(21) Appl. No.: 11/723,981

(22) Filed: Mar. 23, 2007

(30) Foreign Application Priority Data
May 5, 2006 (IT) PD2006A000176

(51) Int. Cl. H05K 5/02

(52) U.S. Cl. 454/184

(57) ABSTRACT

A conditioning apparatus for racks for electrical, electronic and telecommunications instruments and the like, comprising at least one cabinet with inside a rack chassis for instruments, air passage gaps being formed between the door of the cabinet and the rack chassis and between the cabinet back and the rack chassis. The cabinet is open in an upper region onto a first air conveyance element and in a lower region onto a second air conveyance element that are connected respectively to at least one third and one fourth conveyance elements arranged above and below at least one associated air-conditioning module. At least one first, second and third shutters are adapted to allow, modulate or inhibit the air circulation for conditioning of the free cooling type.

The present invention relates to an apparatus for conditioning racks for electrical, electronic and telecommunications instruments or the like.

### BACKGROUND OF THE INVENTION

Together with computers and the use of internal and external data communications networks (the Internet, intranets and the like), supporting chassis for the electrical and electronic instruments and the like which form said computers (servers, auxiliary memories and the like) and define the nodes of such networks (routers and the like), on which these devices can be installed and interfaced in a small space, are increasingly widespread.

Chassis adapted for this purpose are known as racks, and are widespread for example in the field of mobile telephone network sites.

The racks are generally arranged within cabinets, protected against dust and external agents in general.

The main problem linked to racks and to the cabinets which contain them relates to the overheating of the electronic instruments enclosed in the cabinet, especially since the increasing growth of mobile telephony and of other sectors of electronics and computing, has led to an increase in the number of instruments supported by a same rack and packed within a same cabinet.

Problems therefore arise which are linked to the dissipation of the heat generated within the cabinet by such instruments and therefore to the appropriate conditioning of said cabinets.

For example, the increase in the number of racks within a GSM/GPRS network site and the birth of the UMTS network, characterized by greater heat dispersion, has necessarily modified the conditioning requirements in recent years.

An excessive increase in temperature can in fact cause malfunctions of various kinds, to the point of failure of the instruments contained in the cabinet.

Currently, the heat dissipation for such rack cabinets is entrusted to the conditioning system of the room in which the cabinet is located and to the slots or grilles of the cabinet which are adapted to allow the passage of air which arrives from the room among the instruments supported by the rack (or racks) contained in said room.

This cooling method is generally insufficient, especially in the presence of the extremely compact new-generation servers, which generate extremely high power consumptions per unit volume.

Accordingly, regions which are stably too hot (so-called “hot spots”) thus form inside the rack cabinet and locally cause problems to electrical and electronic instruments up to failure.

In order to obviate these drawbacks, this same Applicant has devised a conditioning apparatus which is disclosed and claimed in European Patent Application No. 05110402.4 of Nov. 7, 2005.

This apparatus, particularly for racks for electrical, electronic, telecommunications instruments or the like, is characterized in that it is constituted by at least one cabinet, which is formed by at least one door for accessing its interior, two side walls and a back wall, said cabinet containing a rack chassis for supporting electronic devices and the like; air passage gaps are formed between the at least one door and the rack chassis and the back and said rack chassis; the cabinet is open in an upper region onto a first air conveyance element and in a lower region onto a second air conveyance element, said first and second elements being in turn connected respectively to third and fourth conveyance elements, which are arranged above and below an air-conditioning module, which is laterally adjacent to the cabinet and is adapted to draw warm air from it and inject refrigerated air therein.

Such apparatus can be configured advantageously so as to comprise an alternating series of cabinets and conditioning units and so as to have one extra conditioning unit with respect to the number of rack cabinets, a redundancy which increases significantly the reliability of the apparatus as a whole.

Although this apparatus fully achieves the aim of conditioning the rack chassis and the instruments which it supports, it does not have a safety system which allows to cool the racks even in extreme emergency conditions, such as in the case of simultaneous malfunction of all the air-conditioning modules, a contingency which cannot be tolerated when correct operation for example of servers, routers and electronic devices linked to mobile telephony is at stake.

### SUMMARY OF THE INVENTION

The aim of the present invention is to provide a conditioning apparatus for racks for electrical, electronics and telecommunications instruments and the like which is capable of ensuring the cooling of the electronic instruments contained therein even in case of malfunction of all the air-conditioning modules.

Within this aim, an object of the present invention is to provide an apparatus which, if it has a plurality of rack cabinets, is capable of conditioning them all even in case of failure of any one of the conditioning modules which belong to said apparatus.

A further object of the present invention is to provide an apparatus which can be easily configured for a plurality of rack cabinets arranged close to each other.

Another object of the present invention is to provide an apparatus by way of which it is possible to modulate the flow-rate of the air and change its path for always optimum cooling of the involved racks.

Another object of the present invention is to provide a conditioning apparatus which prevents the formation of regions which are stably too hot inside a rack cabinet.

Another object of the present invention is to provide a conditioning apparatus for racks for electrical, electronic, and telecommunications instruments and the like which can be manufactured cheaply with known systems and technologies.

This aim and these and other objects which will become better apparent hereinafter are achieved by a conditioning apparatus for racks for electrical, electronic and telecommunications instruments and the like, of the type which comprises at least one cabinet formed by at least one door for accessing its interior, two side walls and a back wall, and inside which there is a rack chassis for supporting electronic devices and the like, air passage gaps being formed between said at least one door and said rack chassis and between said back and said rack chassis, said cabinet being open in an upper region onto a first air conveyance element and in a lower region onto a second air conveyance element, said first and second elements being in turn connected respectively to at least one third and one fourth conveyance elements, which are arranged above and below at least one associated air-conditioning module which is laterally adjacent to said cabinet and is adapted to draw warm air from it in order to inject refrigerated air therein, said apparatus being characterized in that at least one of two adjacent conveyance elements has at least one first shutter which is adapted to allow, modulate or inhibit the circulation of air between said two adjacent conveyance elements, said first and second conveyance elements associated with the cabinet being each provided with a second shutter for conditioning of the free cooling type of the interposed cabinet, at least one of said first and second conveyance elements being provided with ventilation means for forced circulation of the ambient air inside said interposed cabinet.

### BRIEF DESCRIPTION OF THE DRAWINGS

Further characteristics and advantages of the invention will become better apparent from the following detailed description of a preferred but not exclusive embodiment thereof, illustrated by way of non-limiting example in the accompanying drawings, wherein:

FIG. 1 is a schematic front view of an apparatus according to the invention;

FIG. 2 is a schematic side view of the path of the air inside a rack cabinet which belongs to the apparatus according to the invention in a first or second operating mode;

FIG. 3 is a perspective view of a cabinet of the apparatus according to the invention;

FIG. 4 is a perspective view of a conditioning module of the apparatus according to the invention;

FIG. 5 is a perspective view of a detail of the apparatus according to the invention;

FIG. 6 is a schematic front view of the apparatus according to the invention in a second embodiment thereof and in a first operating mode;

FIG. 7 is the same front view as FIG. 6, with the apparatus according to the invention in a second operating mode;

FIG. 8 is a schematic side view of the path of the air inside a rack cabinet which belongs to the apparatus according to the invention in a third operating mode;

FIG. 9 is the same front view as FIGS. 6 and 7, with the apparatus according to the invention in a third operating mode;

FIG. 10 is a partially exploded perspective view of a detail of an upper conveyance element of a cabinet of the apparatus according to the invention;

FIG. 11 is a partially exploded perspective view of a detail of a lower conveyance element of a cabinet of the apparatus according to the invention.

### DESCRIPTION OF THE PREFERRED EMBODIMENTS

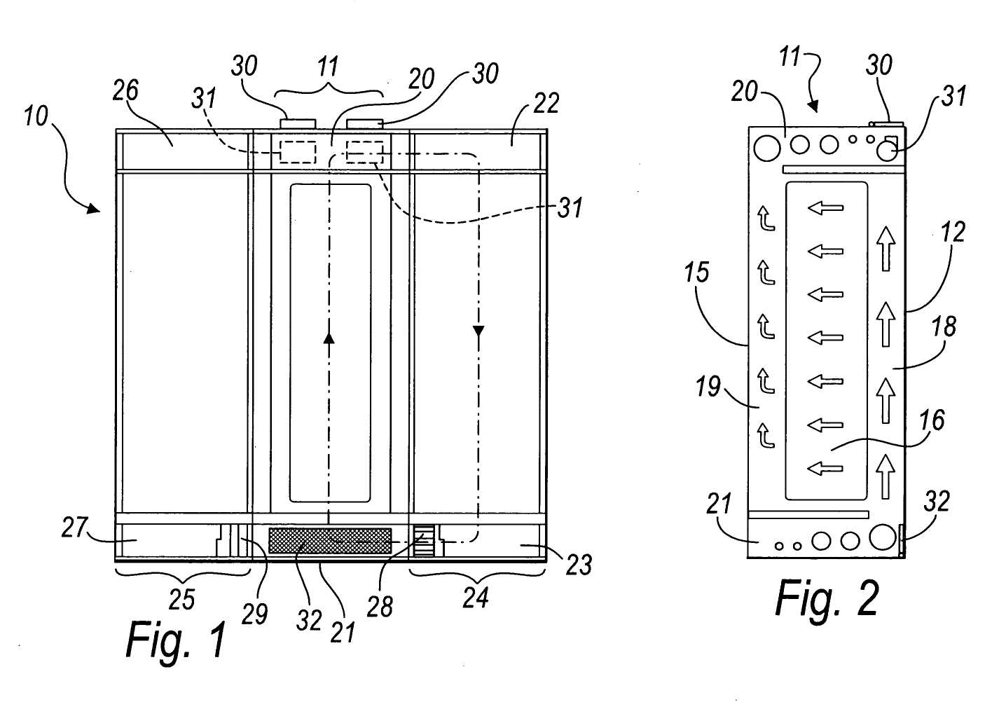

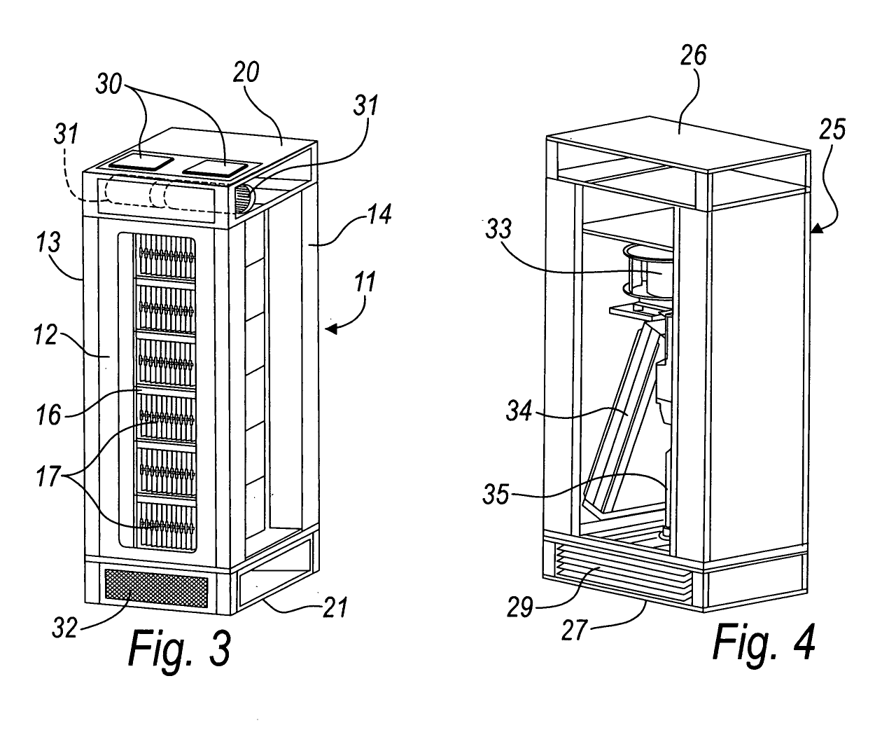

With reference to the figures, a conditioning apparatus for racks for electrical, electronic and telecommunications instruments and the like according to the invention is generally designated by the reference numeral 10 in its first exemplifying and non-limiting embodiment, which is shown in FIG. 1.

The apparatus 10 comprises, in the embodiment of FIG. 1, a cabinet 11 which is formed by a door 12 for accessing its interior, two side walls 13 and 14, and a back 15, and inside which there is a rack chassis 16 for supporting electronic devices or instruments and the like 17.

Air passage gaps 18 and 19 respectively are formed between the door 12 and the rack chassis 16 and between the back 15 and the rack chassis 16.

The cabinet 11 is open in an upper region onto a first air conveyance element 20 and in a lower region onto a second air conveyance element 21.

The first and second elements 20, 21 are in turn connected respectively to a third conveyance element 22 and a fourth conveyance element 23, which are arranged above and below an associated first air-conditioning module 24 which is laterally adjacent to the cabinet 11; the conditioning module 24 is designed to draw warm air from the cabinet 11 and inject refrigerated air therein.

The apparatus 10 also comprises a second air-conditioning module 25, which is laterally adjacent to the cabinet 11 on the opposite side with respect to the first module 24.

The second module 25 has a fifth upper air conveyance element 26 and a sixth lower air conveyance element 27, which are connected to the adjacent conveyance elements 20 and 21 of the cabinet 11.

The lower conveyance elements 23 and 27 of the two conditioning modules 24 and 25 are each provided, in this first embodiment of the apparatus according to the invention, with a first shutter 28 and 29 respectively, which is adapted to allow, modulate or inhibit the circulation of air between said conveyance elements 23 or 27 and the lower conveyance element 21 of the cabinet 11.

The first shutters 28 and 29, of a per se known type, are made of plastic or metallic material, and their configuration, i.e., their degree of opening, is managed by electromechanical actuators, of a per se known type and not shown, which in turn are managed by a central unit for controlling the entire apparatus 10.

The first conveyance element 20 and the second conveyance element 21 associated with the cabinet 11 are each provided with at least one additional shutter for conditioning of the free-cooling type of the interposed cabinet 11, at least one of said first and second conveyance elements 20, 21 being provided with ventilation means for forced circulation of the ambient air within the cabinet 11.

In said first exemplifying and non-limiting embodiment of the invention, the first conveyance element 20 is provided with two second upper shutters 30, each of which is arranged at a part of the ventilation means arranged within the first conveyance element 20.

The ventilation means are constituted by two emergency fans 31, which are clearly visible in the partially exploded view of FIG. 10.

The second upper shutters 30 can be made of metallic or plastic material and can be selectively motorized or gravity-operated.

In said first exemplifying and non-limiting embodiment of the invention, the second conveyance element 21 has a third lower and front shutter 32, also of the motorized or gravity-operated type, which is made of plastic or metallic material.

The conditioning module 24 or 25 contains internally, as exemplified for the module 25 in FIG. 4, a fan 33, an evaporator 34 and a compressor 35.

The upper conveyance elements 20, 22 and 26 are each constituted by a plenum which is connected to the adjacent upper conveyance element, so as to form an air intake manifold on the inside of the cabinet 11 toward the conditioning module 24 or 25.

The lower conveyance elements 21, 23 and 27 are each constituted by a footing panel for resting on the ground, which is connected to an adjacent lower conveyance element by means of a first shutter, said footing panels forming an additional manifold for introducing conditioned air from the active conditioning module to the cabinet 11.

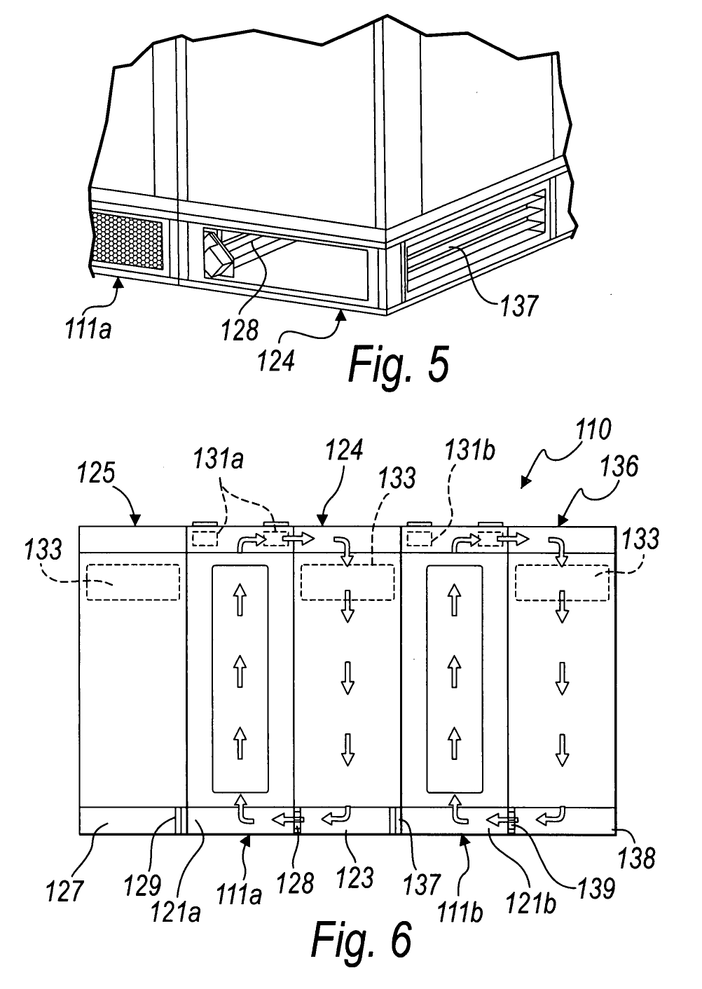

The second embodiment of the apparatus, shown in FIGS. 5 to 9 and designated generally by the reference numeral 110 therein, comprises, as shown by the diagram of FIG. 6, two rack cabinets 111a and 111b, respectively, and three conditioning modules, a first central module 124 and a second module 125 and a third module 136 which are external.

The figures show schematically in broken lines the emergency fans 131a and 131b of the cabinets 111a and 111b and the fans 133 of the conditioning modules.

The apparatus 110 therefore comprises two cabinets 111a and 111b and two conditioning modules, plus one redundant one; this embodiment is to be considered merely an example, since in general the apparatus according to the invention is understood to be composed of N cabinets and (N+1) conditioning modules.

A footing panel 127 of the second external conditioning module 125 has a single first shutter 129, which in FIG. 6 is shown schematically in the closed condition, and the corresponding conditioning module 125 is inactive.

A footing panel 123 of the first central conditioning module 124 is provided with two first shutters 128 and 137, each for adjusting the passage of air alternately toward one or the other of the adjacent footing panels 121a or 121b of the adjacent cabinets; in FIG. 6, the first left shutter 128 is shown schematically open, while the first right shutter 137 is shown schematically closed.

A footing panel 138 of the third conditioning module 136 has a single first shutter 139, which is shown schematically open.

In said first operating mode of the apparatus 110, the first cabinet 111a is cooled by the first central conditioning module 124, the second cabin 111b is cooled by the third module 136, and the second module 125 is switched off or in standby.

FIG. 5 illustrates by way of example the two shutters 128 and 137 of the first module 124.

In FIG. 7, the apparatus 110 is shown schematically as operating in a second mode.

Said second mode entails that the first shutters 129 and 139 respectively of the second module 125 and of the third module 136 are open, while the first shutters of the first central module 124 are both closed.

Said second mode therefore connects the first cabinet 111a to the second module 125 and the second cabinet 111b to the third module 136, while the first central module 124 is switched off or in standby.

The configuration of the apparatus according to the invention with N cabinets and N+1 modules allows to always have one conditioning module in standby available to be connected to a cabinet which is in critical conditions due to the malfunction of the conditioning module associated therewith at that time, and allows to reduce the workload of each conditioning module by alternately placing in standby, at regular intervals, one after the other, all the conditioning modules or at least some of them.

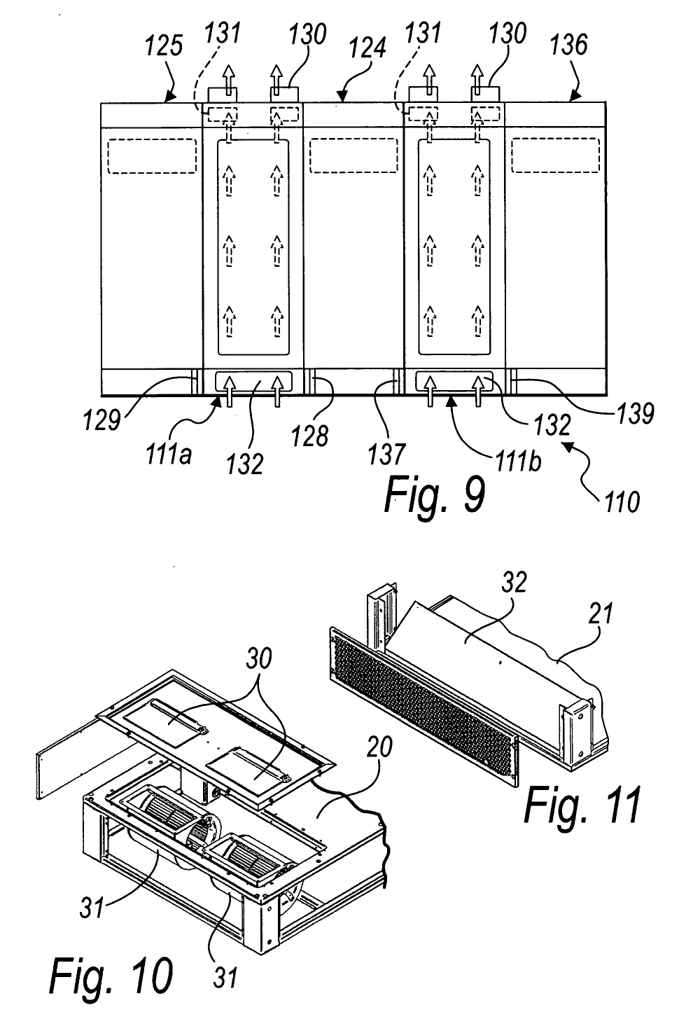

FIG. 9 illustrates a third operating mode of the apparatus 110 according to the invention.

Said third emergency mode entails that the three conditioning modules 124, 125 and 136 are inoperative for any reason and the respective first shutters 128 and 137, 129 and 139 are all closed.

In this situation, the cooling of the cabinets 111a and 111b is ensured by the emergency fans 131, simultaneously with the activation of which the second shutters 130 and third shutters 132 are opened.

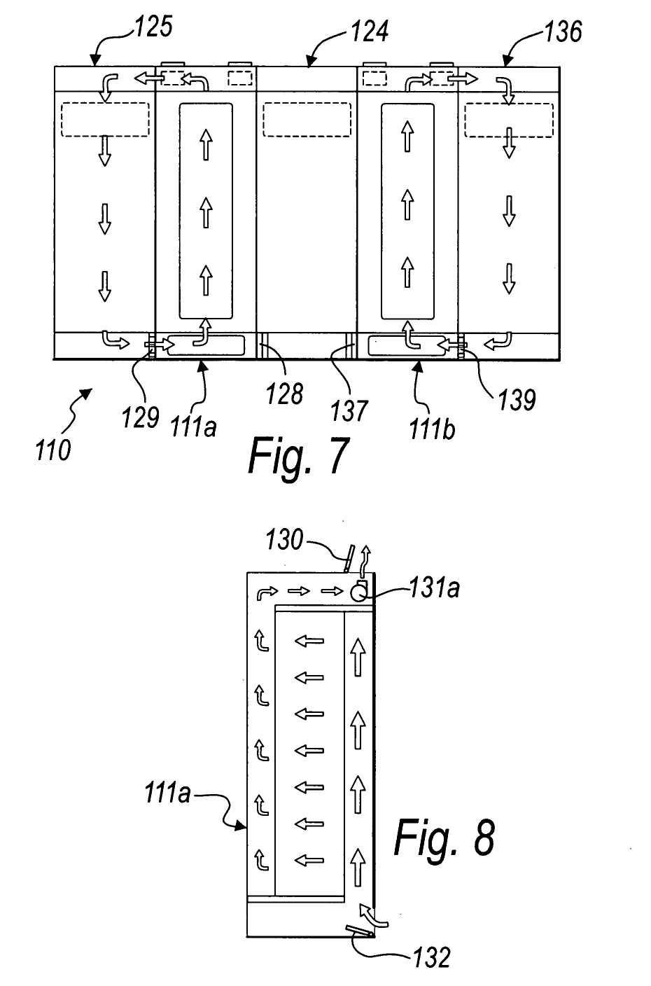

In this mode, the cabinets 111a and 111b, isolated from the nearby inactive conditioning modules, are crossed from the bottom upward by ambient air, which passes through them along the path shown schematically in FIG. 8.

Said third operating mode can be started manually or automatically by the electronic control unit of the apparatus 110.

The emergency fans 131a and 131b are powered by uninterruptible power supplies (UPS), which are internal or external to the rack cabinet, so as to make the system independent of any electric power outages.

In practice it has been found that the invention thus described solves the problems noted in known types of conditioning apparatus for racks for electrical, electronic and telecommunications instruments and the like.

In particular, the present invention provides a conditioning apparatus for racks for electrical, electronic and telecommunications instruments and the like which is capable of ensuring the cooling of the electronic instruments contained therein even in case of malfunction of all the air-conditioning modules, thanks to the emergency fans 31 and 13a and 13b which are installed in the upper conveyance elements of the cabinets and to the corresponding associated shutters.

Further, the present invention provides an apparatus which, if it is provided with a plurality of rack cabinets, can condition them all even if any one of the conditioning modules that belong to the apparatus fails, thanks to the modification of the air passage paths allowed by the shutters with which the conditioning modules and the cabinets are provided.

Moreover, the present invention provides an apparatus which can be installed easily for a plurality of rack cabinets arranged in the vicinity of each other.

Further, the present invention provides an apparatus by way of which it is possible to modulate the air flow-rate and change its path for an always optimum cooling of the involved racks.

Moreover, the present invention provides an apparatus for conditioning racks for electrical, electronic and telecommunications instruments and the like which can be manufactured cheaply with known systems and technologies.

In practice, the materials employed, so long as they are compatible with the specific use, as well as the dimensions, may be any according to requirements and to the state of the art.

The disclosures in Italian Patent Application No. PD2006A000176 from which this application claims priority are incorporated herein by reference.

What is claimed is:

1. A conditioning apparatus for racks for electrical, electronic and telecommunications instruments, comprising: at least one cabinet provided with at least one door for accessing its interior, two side walls and a back wall and having openings in upper and lower regions thereof; a rack chassis located inside said at least one cabinet for supporting the instruments; air passage gaps formed between said at least one door and said rack chassis and between said back and said rack chassis; at least one associated air-conditioning module which is laterally adjacent to said at least one cabinet and is adapted to draw warm air from the cabinet in order to inject refrigerated air therein; a first air conveyance element arranged at the upper opening of said at least one cabinet; a second air conveyance element arranged at the lower opening of said at least one cabinet; at least one third and one fourth air conveyance elements, which are arranged above and below said air-conditioning module and being connected, respectively, to said first and second air conveyance elements, and wherein at least one of two said first to fourth air conveyance elements that are adjacent to each other has at least one first shutter which is adapted to allow, modulate or inhibit circulation of air between the two adjacent air conveyance elements, said first and second air conveyance elements being associated with said at least one cabinet that is located in an interposed position and being each provided with at least one second upper shutter and at least one third lower front shutter for conditioning of a free cooling type of said at least one interposed cabinet, at least one of said first and second air conveyance elements being provided with ventilation means for forced circulation of ambient air inside said at least one interposed cabinet.

2. The apparatus of claim 1, comprising a first air-conditioning module and a second air-conditioning module, said second air-conditioning module being laterally adjacent to said at least one cabinet on a side thereof that is opposite with respect to said first air-conditioning module.

3. The apparatus of claim 2, wherein said first and second air conveyance elements of said at least one cabinet are connected respectively to the third air conveyance element and the fourth air conveyance element, which are arranged above and below the associated first air-conditioning module, said second air-conditioning module being provided with a fifth upper air conveyance element and a sixth lower air conveyance element, which are connected to the adjacent first and second air conveyance elements of the at least one cabinet.

4. The apparatus of claim 3, wherein said fourth and sixth lower conveyance elements of the two air-conditioning modules are each provided with a said first shutter which is adapted to allow, modulate or inhibit air circulation between said fourth and sixth air conveyance elements and the second lower conveyance element of the at least one cabinet.

5. The apparatus of claim 4, further comprising electromechanical or mechanical actuators and a central control unit for overall control of the apparatus, said first shutters being made of plastic or metallic material and configured with a suitable degree of opening that is managed by said actuators, which in turn are managed by said central control unit.

6. The apparatus of claim 3, wherein said first air conveyance element has two second upper shutters, each of which is arranged at a part of the ventilation means, which are arranged within said first air conveyance element.

7. The apparatus of claim 6, wherein said ventilation means are constituted by a pair of emergency fans.

8. The apparatus of claim 6, wherein said second upper shutters are made of metallic or plastic material.

9. The apparatus of claim 6, wherein said second shutters are selectively motorized or gravity-operated.

10. The apparatus of claim 6, wherein said second conveyance element has a third lower shutter, of the motorized or gravity-operated type, made of plastic or metallic material.

11. The apparatus of claim 6, wherein said first, third and fifth upper conveyance elements are each constituted by a plenum which is connected to an adjacent said upper conveyance element so as to form a manifold for drawing inside air from said at least one cabinet toward a said air-conditioning module.

12. The apparatus of claim 6, wherein said second, fourth and sixth lower conveyance elements are each constituted by a footing panel which is ground rested and is connected to an adjacent one of said lower conveyance elements by way of a said first shutter, said footing panels forming an additional manifold for introducing conditioned air from an active one of said air-conditioning modules into the at least one cabinet.

13. The apparatus of claim 12, comprising N said rack cabinets and N+1 said air-conditioning modules.

14. The apparatus of claim 12, comprising two said rack cabinets and three said air-conditioning modules, wherefrom a first central one, and a second one and a third one which are external.

15. The apparatus of claim 14, wherein the footing panel of the second external air-conditioning module has a single first shutter.

16. The apparatus of claim 15, wherein the footing panel of the first central conditioning module is provided with two first shutters, each for adjusting an air passage alternately toward one or the other of the footing panels that are adjacent of the two rack cabinets that are adjacent.

17. The apparatus of claim 16, wherein a said footing panel of said third air-conditioning module has a single first shutter.

18. The apparatus of claim 7, wherein said emergency fans are powered by uninterruptible power supplies which are provided internal or external with respect to the rack cabinet so as to render the apparatus independent of any electric power outages.
